(19) United States
(12) Patent Application Publication
(10) Pub. No.: US 2006/0021793 A1
(43) Pub. Date: Feb. 2, 2006

(54) Wiring board and magnetic disk apparatus

(75) Inventor: Makoto Aoki, Fukaya-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/136,455

(22) Filed: May 25, 2005

(30) Foreign Application Priority Data
Jul. 30, 2004 (JP) 2004-222795

(51) Int. Cl. H05K 1/18

(52) U.S. Cl. 174/260

(57) ABSTRACT

A through hole 2 is formed in an end portion of a wiring board main body 1. A land 3 formed around the through hole 2 is in a shape having partially lacking portions symmetrically formed on an end portion side of the wiring board main body 1 and on an opposite side of the end portion side. A component 5 is fixed to the land 3 by solder 4.

### CROSS0REFERENCE TO RELATED APPLICATION

This application is based upon and claims the benefit of priority from the prior Japanese Patent Application No. 2004-222795, filed on Jul. 30, 2004; the entire contents of which are incorporated herein by reference.

### BACKGROUND OF THE INVENTION

1. Field of the Invention

The present invention relates to a wiring board and a magnetic disk apparatus, and more particularly, to a wiring board suitable for a small magnetic disk apparatus and the like and to a magnetic disk apparatus having such a wiring board.

2. Description of the Related Art

As portable devices and electronic devices get more highly functional and more reduced in size and weight, downsizing has come in demand also for a magnetic disk apparatus which is a typical apparatus for storing a large volume of digital information. A disk enclosure of such a small magnetic disk apparatus housing disks and so on itself is small in size, and thus wiring boards provided therein or attached thereto also need to respond to the downsizing.

As a wiring board as described above, known is one that has a through hole for screwing in an end portion of its wiring board main body and is fixed to an apparatus main body and the like with a fixing screw inserted in the through hole. It is also known that for the purpose of grounding in this fixing portion, a ring-shaped pad or a C-shaped pad made of a conductive material is provided around the through hole (see, for example, U.S. Pat. No. 4,851,614).

For example, in a magnetic disk apparatus or the like, in order to respond to its downsizing, improvement in density and reduction in size have been under progress also in a wiring board. Therefore, it is desired that the aforesaid through hole for screwing and the like be disposed as close to the end portion of the wiring board main body as possible to secure a wide area usable for forming an electric circuit. Further, it is also desired that the aforesaid fixing screw protrude from the wiring board main body as little as possible, thereby reducing the dimension in a thickness direction.

FIG. 11 shows an example of the structure in which a head of the fixing screw does not protrude from the wiring board main body. Specifically, in FIG. 11, a land 30 is provided around a through hole 2 for screwing formed in a wiring board main body 1, and a washer-shaped component 5 is fixed to the land 30 by a fixing member such as solder 4. The washer-shaped component 5 has, in its center portion, an insertion hole 5a smaller in diameter than the through hole 2 for having the screw 6 inserted thereto, and an upper face of the component 5 receives the head of the screw 6. Such a structure enables an upper face of the screw 6 to be substantially on the same level as an upper face of the wiring board main body 1 when the wiring board main body 1 is fixed to the magnetic disk apparatus main body 20 and so on.

The aforesaid through hole 2 and land 30 are preferably disposed in the end portion of the wiring board main body 1, as previously described. However, in the end portion of the wiring board main body 1, an area of, for example, about 0.3 mm is an area where a wiring pattern or a land cannot be provided due to restrictions in its manufacturing processes. Therefore, if the through hole 2 and the land 30 are disposed close to the end portion of the wiring board main body 1, the land 30 comes to have not a ring shape but a substantially C-shape or the like having a lacking part on the end portion side of the wiring board main body 1, as shown in FIG. 12(a).

It has been found, however, that the C-shaped land 3 has a high possibility of causing a displacement of the component 5 to the opposite side (left side in the drawing) of the end portion, as shown in FIG. 12(c) when the land 30 with the solder 4 and the component 5 placed thereon is heated in a reflow furnace for melting and soldering as shown in FIG. 12(b). Fixing the component 5 being left displaced causes misalignment between the wiring board 1 and the magnetic disk apparatus main body 20 when the wiring board 1 is screw-fixed to the magnetic disk apparatus main body 20 and so on. As a result, stress is given to a connector and the like for electrical connection, leading to a problem of a higher occurrence rate of product fault such as faulty connection.

### SUMMARY OF THE INVENTION

The present invention was made to solve the conventional problems as described above, and it is an object of the present invention to provide a highly reliable wiring board and magnetic disk apparatus capable of preventing the displacement in fixing a component to a land and capable of responding to downsizing and higher density design.

A wiring board according to one of the aspects of the present invention includes: a wiring board main body on which a conductor pattern in a predetermined shape is formed; a land provided near an end portion of the wiring board main body and having partly lacking portions symmetrically formed on an end portion side of the wiring board main body and on an opposite side of the end portion side; and a component fixed to the land by a fixing member.

A wiring board according to another aspect of the present invention includes: a wiring board main body on which a conductor pattern in a predetermined shape is formed; a through hole for screwing provided near an end portion of the wiring board main body; a land formed around the through hole and having partly lacking portions symmetrically formed on an end portion side of the wiring board main body and on an opposite side of the end portion side; and a plate-shaped component fixed to the land by a fixing member and having in a center portion an insertion hole to which a screw is inserted.

A magnetic disk apparatus according to still another aspect of the present invention includes: a wiring board having a wiring board main body on which a conductor pattern in a predetermined shape is formed, a through hole for screwing provided near an end portion of the wiring board main body, a land formed around the through hole and having partly lacking portions symmetrically formed on an end portion side of the wiring board main body and on an opposite side of the end portion side, and a plate-shaped component fixed to the land by a fixing member and having in a center portion an insertion hole to which a screw is inserted; and a magnetic disk apparatus main body that includes a head carriage provided with a magnetic head for input/output of an electrical signal, and a magnetic disk from/to which magnetic information is read/written by the magnetic head provided in the head carriage, and that is fixed to the wiring board by the screw inserted to the through hole and the insertion hole.

### BRIEF DESCRIPTION OF THE DRAWINGS

FIG. 1 is a view showing a schematic structure of an entire wiring board according to an embodiment of the present invention.

FIG. 2 is an enlarged view showing a structure of an essential portion of the wiring board in FIG. 1.

FIG. 3 is a cross-sectional view showing the structure of the wiring board in FIG. 2 taken along the A-A line.

FIG. 4(a) to FIG. 4(c) are views showing processes of fixing a component of the wiring board in FIG. 1.

FIG. 5 is a view showing a schematic structure of a magnetic disk apparatus according to an embodiment of the present invention.

FIG. 6 is an enlarged view showing a fixing portion of the wiring board and a magnetic disk apparatus main body in FIG. 5.

FIG. 7 is a view showing a schematic structure of the magnetic disk apparatus main body in FIG. 5.

FIG. 8 is a view showing a schematic structure of an essential portion of another embodiment of the present invention.

FIG. 9 is a view showing a schematic structure of an essential portion of still another embodiment of the present invention.

FIG. 10 is a view showing a schematic structure of an essential portion of yet another embodiment of the present invention.

FIG. 11 is an enlarged view showing an essential portion of a conventional wiring board.

FIG. 12(a) to FIG. 12(c) are views showing processes of fixing a component of the wiring board in FIG. 11.

### DESCRIPTION OF THE EMBODIMENTS

Hereinafter, embodiments of the present invention will be described with reference to the drawings for detailed description of the present invention.

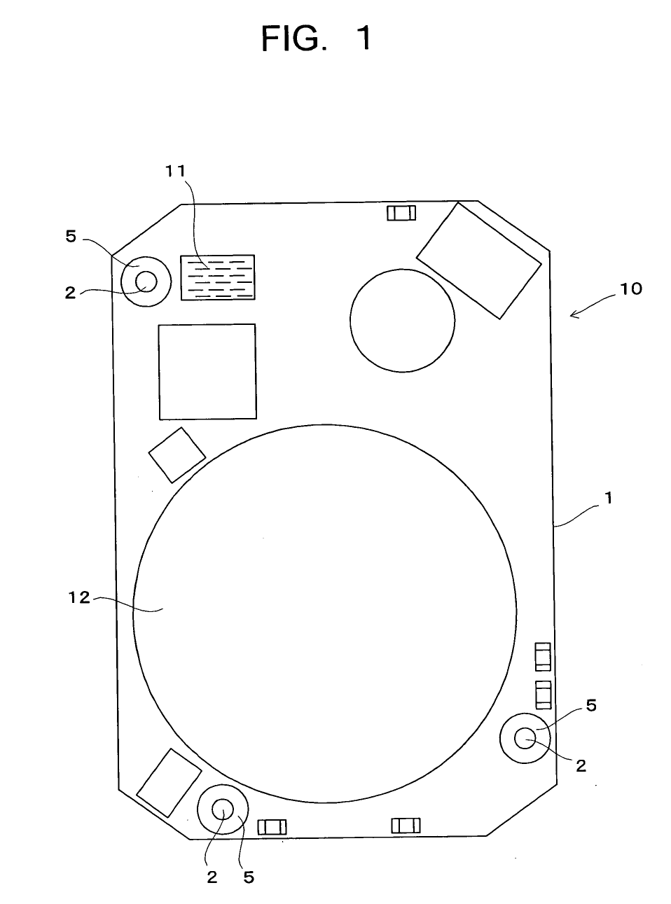

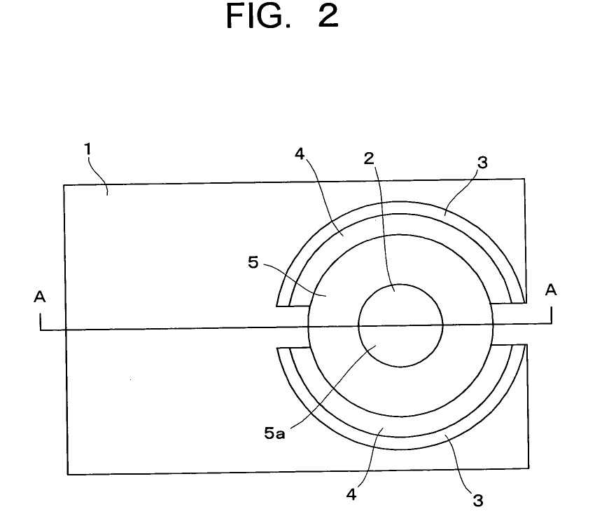

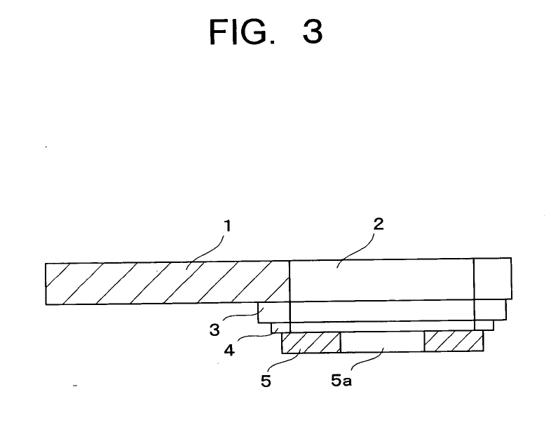

FIG. 1 to FIG. 3 show a schematic structure of a wiring board according to an embodiment of the present invention, FIG. 1 showing a plane structure of the entire wiring board, FIG. 2 showing an enlarged essential portion of the wiring board in FIG. 1, and FIG. 3 showing a cross-sectional structure taken along the A-A line in FIG. 2.

As shown in FIG. 1, a wiring board main body 1 forming a wiring board 10 has at its end portions a plurality of (totally three in FIG. 1) through holes 2 for screwing, and washer-shaped components 5 are fixed to the through holes 2 respectively. On the wiring board main body 1, a not-shown predetermined conductor pattern is formed and predetermined electronic components are mounted. Further, in FIG. 1, 11 denotes a connector for electrical connection to a later-described magnetic disk apparatus main body 20, and 12 denotes an opening to which a disk of the magnetic disk apparatus main body 20 is to be inserted.

As shown in FIG. 2 and FIG. 3, a land 3 is provided around each of the through holes 2, and the component 5 is fixed to each of the lands 3 by a fixing member such as solder 4. The component 5 is made of metal or the like and has a thin plate shape, and it has in its center portion an insertion hole 5a for having a later-described screw inserted thereto. As for the dimension of the component 5, it is, for example, 2.8 mm in outside diameter, 1.2 mm in inside diameter, and 0.1 mm in thickness.

As shown in FIG. 2, the land 3 has partially lacking portions symmetrically formed on an end portion side of the wiring board main body 1 (right side in FIG. 2) and on the opposite side (left side in FIG. 2) of the end portion side. In other words, the land 3 is composed of two separate portions in a parenthesis shape (in a ( ) shape) facing each other, and is in a symmetrical shape with respect to its center axis. As for the dimension of the through hole 2, it is, for example, 2.2 mm in inside diameter. As for the dimension of the land 3, it is, for example, 2.96 mm in outside diameter and 2.5 mm in inside diameter. Incidentally, in this embodiment, the wiring board main body 1 is in a shape with an incision so as to match the shape of the lacking portion of the land 3 on the end portion side of the wiring board main body 1, but the incision of the wiring board main body 1 is not necessarily required.

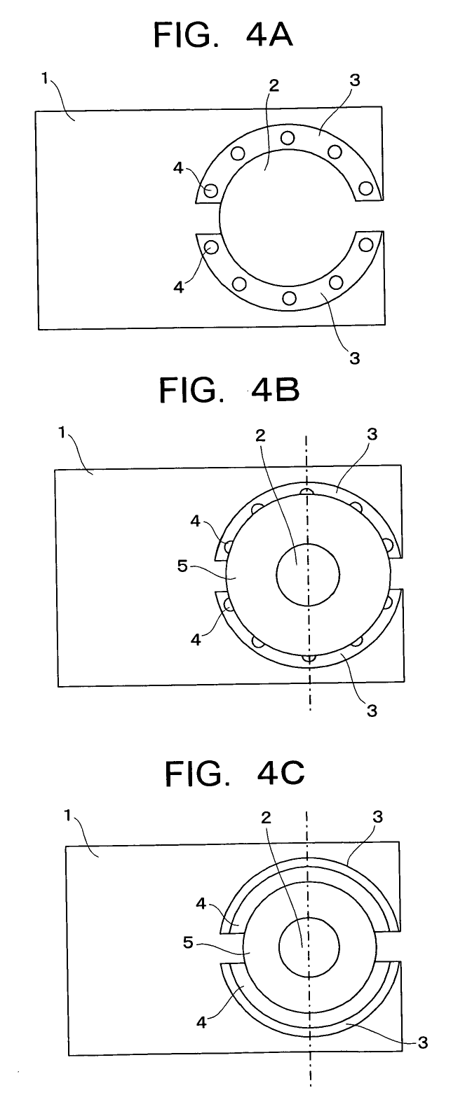

An example of processes for fixing the component 5 to the land 3 structured above will be described with reference to FIG. 4(a) to FIG. 4(c). As shown in FIG. 4(a), the solder 4 as the fixing member is first put on the land 3. Next, as shown in FIG. 4(b), the component 5 is placed on the solder 4. Next, the solder 4 is melted in a reflow furnace or the like, and as shown in FIG. 4(c), the land 3 and the component 5 are fixed to each other. In this embodiment, the land 3 in the symmetrical shape, not in a C-shape or the like, prevents one-sided flow of the solder 4 when the solder 4 is melted, which can prevent the occurrence of the displacement of the component 5.

A displacement amount when the land 3 and the component 5 were fixed to each other through the above processes was measured on ten samples, and the measurement result showed that the minimum value (absolute value) of the displacement amount was 0.01 mm and the maximum value (absolute value) thereof was 0.03 mm. Further, the same measurement was conducted for comparison regarding the land 30 having the aforesaid C-shape, and the measurement result showed that the minimum value (absolute value) was 0.06 mm and the maximum value (absolute value) was 0.1 mm. As is seen from the results, this embodiment can greatly reduce the displacement amount of the component 5 compared to the conventional example.

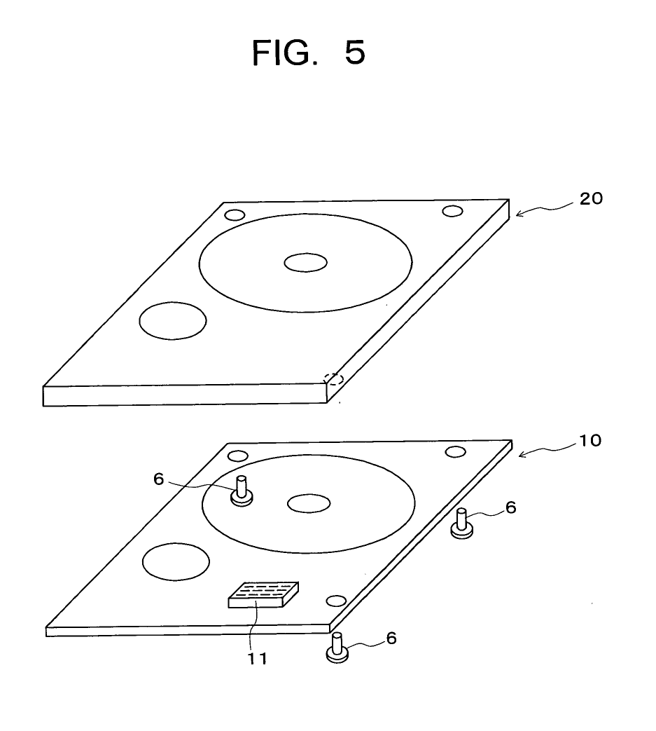

As shown in FIG. 5, the wiring board 10 structured above is fixed to the magnetic disk apparatus main body 20 by the screws 6 inserted to the through holes 2 and the insertion holes 5a of the components 5, so that a magnetic disk apparatus is formed. The magnetic disk apparatus main body 20 is in a substantially plate shape, and the wiring board 10 is fixed to a rear face side of the magnetic disk apparatus main body 20.

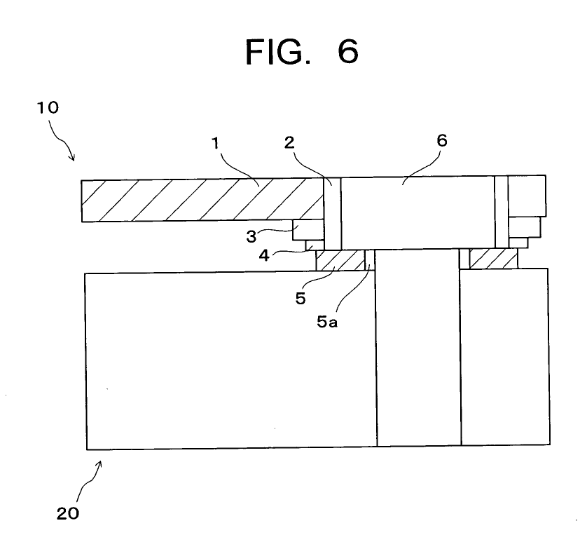

At this time, as shown in FIG. 6, upper faces of the components 5 receive heads of the screws 6, and upper faces of the screws 6 become substantially on the same level as an upper face of the wiring board main body 1. That is, this is a state in which the heads of the screws 6 do not protrude from the upper face of the wiring board main body 1. Further, the wiring board 10 and the magnetic disk apparatus main body 20 are electrically grounded via the lands 3, the screws 6, and so on.

Electrical connection of signal lines and so on between the wiring board 10 and the magnetic disk apparatus main body 20 is realized by connection of the aforesaid connector 11 on the wiring board 10 side and a not-shown connector provided on the magnetic disk apparatus main body 20 side. At this time, since the wiring board 10 and the magnetic disk apparatus main body 20 are fixed in accurate alignment by the screws 6, stress application to the connector 11 and so on can be prevented.

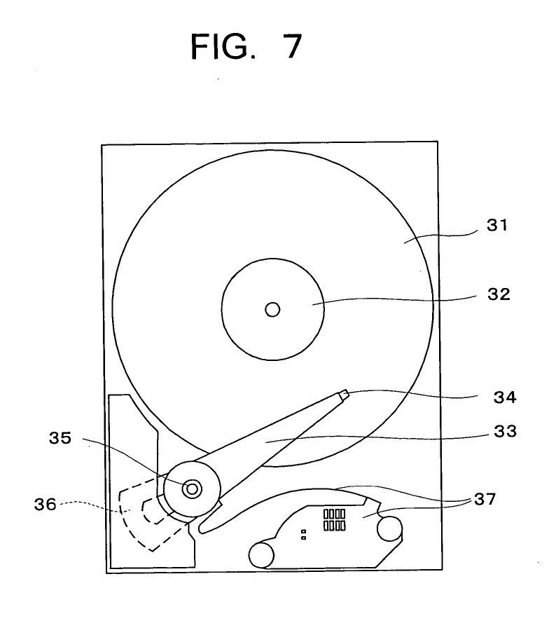

The structure of a magnetic disk apparatus including the wiring board structured above will be described. As shown in FIG. 7, the magnetic disk apparatus includes a magnetic disk 31, a disk damper 32, a head carriage 33, a magnetic head 34, a pivot 35, a voice coil motor 36, and a head carriage communication wiring board 37. The entire magnetic disk apparatus has a dimension of, for example, 32 mm in length and 24 mm in width.

The magnetic disk 31 is a disk-shaped medium retaining information as magnetic patterns in a circumferential direction, and a magnetic signal is written/read thereto/therefrom by the magnetic head 34 provided at a tip of the head carriage 33 moving in a radial direction of the magnetic disk 31. The disk damper 32 fastens and fixes a rotation center of the magnetic disk 31 to a spindle motor (not shown) side provided on an underside thereof. The head carriage 33 moves the magnetic head 34 provided at the tip thereof in the radial direction while keeping the magnetic head 34 lifted above the magnetic disk.

The magnetic head 34 converts an electrical signal to a magnetic signal in order to write information to the magnetic disk 31 and converts a magnetic signal to an electrical signal in order to read information from the magnetic disk 31. Write/read electrical signals are transferred from/to the head carriage communication wiring board 37 connected to the head carriage 33. The pivot 35 is the center of the movement (rotation) of the head carriage 33 and rotatable supports the head carriage 33. The voice coil motor 36 is a driving source for rotating the head carriage 33 with respect to the pivot 35.

The head carriage communication wiring board 37 communicates with (is connected to) the head carriage 33 to transfer signals exchanged with the magnetic head 34. These signals may include a signal to the voice coil motor 36. Further, as shown in the drawing, the head carriage communication wiring board 37 has two parts: one is a portion changing in its flexure state according to the rotation of the head carriage 33 and functioning mainly as a cable for signal transfer; the other is an area in a fixed shape, continuing from this portion and mainly serving as a mounting area of electronic components.

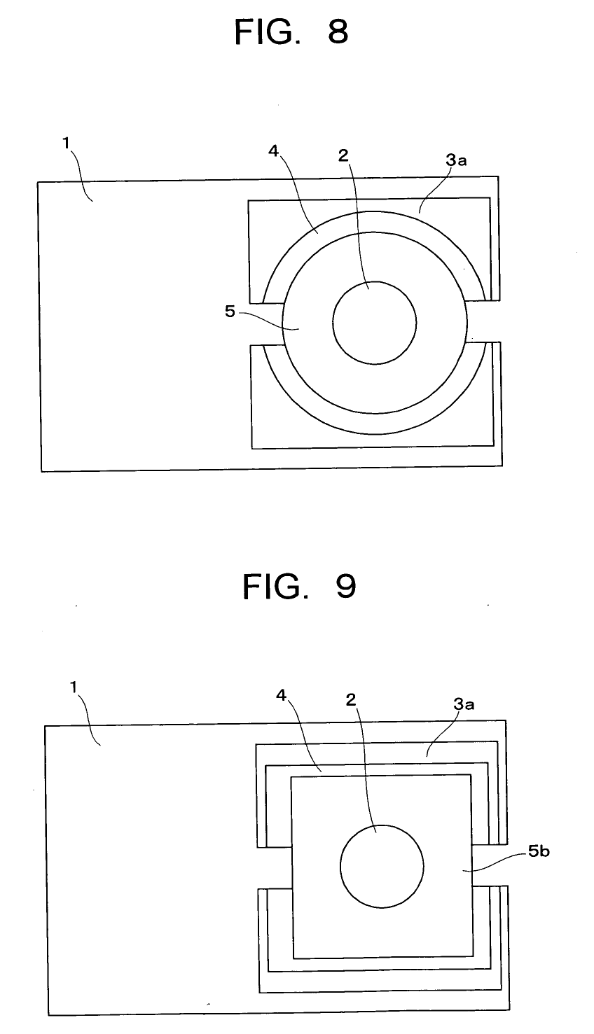

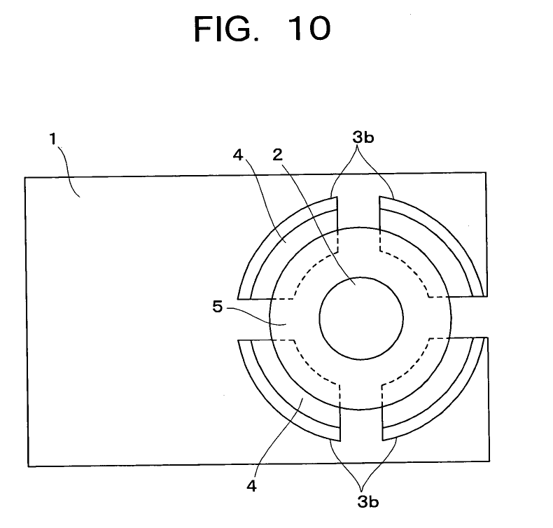

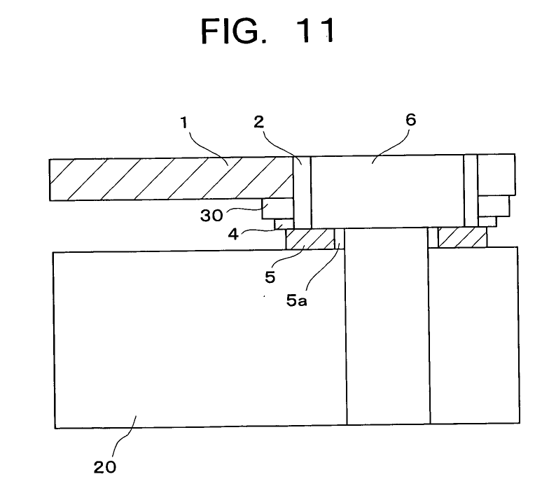

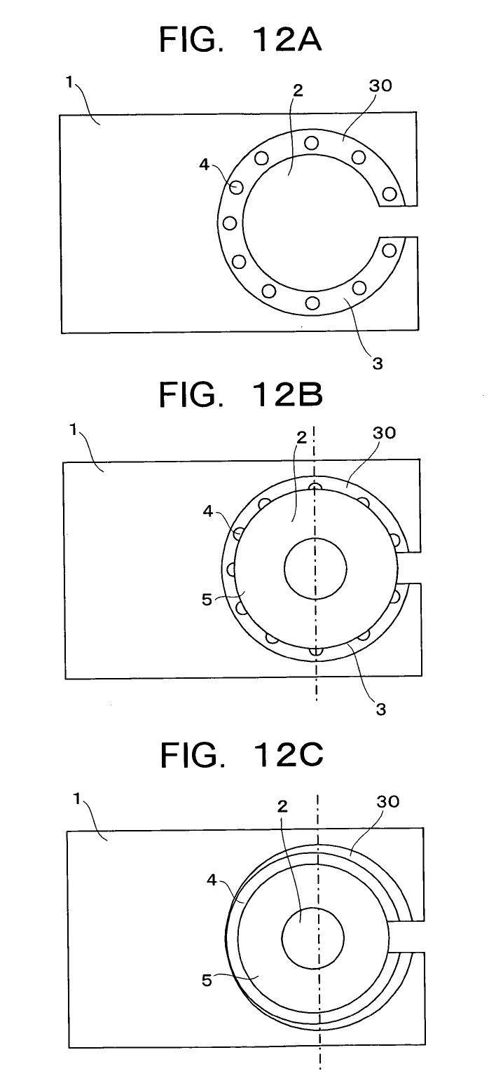

It should be noted that, though the foregoing embodiment has described the case where the land 3 in the parenthesis shape is used, the shape of the land is not limited to such a shape. For example, as shown in FIG. 8, any land in a symmetrical shape may be used such as a land 3a with a quadrangular outer shape and the like. Further, when the land 3a in such a shape is used, a component 5b with a quadrangular outer shape and the like as shown in FIG. 9 can be used. Moreover, the land is not limited to be divided into two, but for example, a land symmetrically divided into four such as a land 3b shown in FIG. 10 may be used, or a land divided into a larger number of portions, for example, into six may be used. Furthermore, the component is not limited to a washer-shaped component for screwing but any component may be used.

What is claimed is:

1. A wiring board, comprising:
a wiring board main body on which a conductor pattern in a predetermined shape is formed;
a land provided near an end portion of said wiring board main body and having partly lacking portions symmetrically formed on an end portion side of said wiring board main body and on an opposite side of the end portion side; and
a component fixed to said land by a fixing member.

2. A wiring board according to claim 1,
wherein the fixing member is solder and the solder is melted by reflow to fix said component to said land.

3. A wiring board according to claim 1,
wherein said land is formed of two separate portions in a parenthesis shape.

4. A wiring board comprising:
a wiring board main body on which a conductor pattern in a predetermined shape is formed;
a through hole for screwing provided near an end portion of said wiring board main body;
a land formed around said through hole and having partly lacking portions symmetrically formed on an end portion side of said wiring board main body and on an opposite side of the end portion side; and
a plate-shaped component fixed to said land by a fixing member and having in a center portion an insertion hole to which a screw is inserted.

5. A wiring board according to claim 4,
wherein the fixing member is solder and the solder is melted by reflow to fix said component to said land.

6. A wiring board according to claim 4,
wherein said land is formed of two separate portions in a parenthesis shape.

7. A magnetic disk apparatus, comprising:
a wiring board having a wiring board main body on which a conductor pattern in a predetermined shape is formed, a through hole for screwing provided near an end portion of the wiring board main body, a land formed around the through hole and having partly lacking portions symmetrically formed on an end portion side of the wiring board main body and an opposite side of the end portion side, and a plate-shaped component fixed to the land by a fixing member and having in a center portion an insertion hole to which a screw is inserted; and
a magnetic disk apparatus main body that includes a head carriage provided with a magnetic head for input/output of an electrical signal, and a magnetic disk from/to which magnetic information is read/written by the magnetic head provided in said head carriage, and that is fixed to said wiring board by the screw inserted to the through hole and the insertion hole.

8. A magnetic disk apparatus according to claim 7,
wherein said magnetic disk apparatus main body is substantially in a plate shape, and said wiring board is fixed to a rear face side of said magnetic disk apparatus main body.

9. A magnetic disk apparatus according to claim 7,
wherein the fixing member is solder and the solder is melted by reflow to fix the component to the land.

10. A magnetic disk apparatus according to claim 7,
wherein the land is formed of two separate portions in a parenthesis shape.
